(19) United States
(12) Patent Application Publication
(10) Pub. No.: US 2011/0147050 A1
(43) Pub. Date: Jun. 23, 2011

(54) PRINTED WIRING BOARD AND METHOD FOR MANUFACTURING PRINTED WIRING BOARD

(76) Inventor: Eiji Ishikawa, Tokyo (JP)

(21) Appl. No.: 13/059,112

(22) PCT Filed: Aug. 24, 2009
(86) PCT No.: PCT/JP2009/004058

§ 371 Date: Feb. 15, 2011

(30) Foreign Application Priority Data
Aug. 29, 2008 (JP) 2008-220705

(51) Int. Cl. H05K 1/02; H05K 3/10

(52) U.S. Cl. 174/251; 29/846; 29/847

(57) ABSTRACT

A printed wiring board (1) includes a substrate (11). A groove (111) extending in a direction perpendicular to the thickness direction of the substrate (11) is formed in the substrate (11), and a wiring (12) is provided to fill the groove (111).

### TECHNICAL FIELD

The present invention relates to a printed wiring board and a method for manufacturing the printed wiring board.

### BACKGROUND ART

A conventional printed wiring board includes an insulating layer and a circuit layer formed on the insulating layer. The wirings forming the circuit layer are formed on the insulating layer.

For example, according to Patent Document 1, copper foil on the insulating layer is selectively removed, and wirings are formed on the insulating layer.

### PRIOR ART DOCUMENTS

### Patent Document

[Patent Document 1] Japanese Laid-Open Patent Publication No. 2006-352103

### DISCLOSURE OF THE INVENTION

Since each wiring is required to have high durability to tolerate a predetermined amount of current, each wiring has a wiring width equal to or greater than a predetermined value. To further improve the durability, the wiring width may be made even greater. However, there is a limit to the size of a printed wiring board. Therefore, it is difficult to improve the durability by increasing the wiring width.

On the other hand, the thickness of each wiring might be made greater. In that case, however, the thickness of the printed wiring board also becomes greater, and it becomes difficult to satisfy the demand for smaller-sized printed wiring boards.

The present invention provides a printed wiring board that includes a substrate. A groove extending in a direction perpendicular to a thickness direction of the substrate is formed in the substrate. A wiring is provided to fill the groove.

According to the present invention, the wiring is provided so as to fill the groove formed in the substrate.

Accordingly, even if the wiring width is the same as that of a conventional wiring, a large cross-sectional area can be secured for the wiring by adjusting the groove depth. With this arrangement, the durability of the wiring can be made higher, and increases in size of the printed wiring board can be restrained.

Further, the wiring fills the groove and preferably has an end portion protruding from the groove in the wiring thickness direction and spreading along the substrate in a flange-like shape.

With this structure, a cross-sectional area can be secured for the wiring, and the durability of the wiring can be made higher.

Further, the groove is preferably a through groove that penetrates through the substrate, and the wiring preferably has a pair of end portions each protruding from an opening of the groove in the wiring thickness direction and spreading along the substrate in a flange-like shape.

By spreading along the surface of the substrate in a flange-like shape, the pair of end portions extending in the wiring thickness direction can prevent the wiring from slipping out of the groove.

Further, the wiring is a power wire, and a signal line formed by another wiring different from the wiring is preferably formed on the substrate.

Since a large amount of current flows through a power wire in general, a large cross-sectional area needs to be secured for a power wire by increasing the width of the wire or the thickness of the wire.

Therefore, by forming the power wire to fill the groove in the substrate, increases in size of the printed wiring board can be restrained certainly, and the durability of the power wire can be made higher.

Also, by forming another wiring different from the wiring on the substrate, there is no need to form many grooves in the substrate. Accordingly, complicated procedures can be skipped for manufacturing the printed wiring board.

Further, the printed wiring board is preferably a rigid wiring board or a rigid flexible wiring board, and the groove and the wiring are preferably provided in a rigid region.

The above printed wiring board can be manufactured by the following manufacturing method.

That is, the manufacturing method according to the present invention is a method for manufacturing a printed wiring board that includes: forming a groove extending in a board having a substrate, the groove extending in a direction perpendicular to the thickness direction of the substrate; and forming a wiring by filling the groove with a conductor.

Further, the board preferably includes the substrate and a first conductor layer provided on the substrate. In the step of forming the groove, the groove to penetrate through the first conductor layer and reach the inside of the substrate is preferably formed. In the step of forming the wiring, the wiring that fills the groove and has an end portion protruding from the groove in the wiring thickness direction and spreading along the substrate in a flange-like shape is preferably formed by filling the groove with the conductor and selectively removing the first conductor layer.

Also, the board preferably includes a second conductor layer that is provided on the opposite side of the substrate from the first conductor layer. In the step of forming the groove, the groove is preferably formed so as to penetrate through the first conductor layer and the substrate. In the step of forming the wiring, the wiring that fills the groove and has a pair of end portions each protruding from an opening of the groove in the wiring thickness direction and spreading along the substrate in a flange-like shape is preferably formed by filling the groove with the conductor and selectively removing the first conductor layer and the second conductor layer.

Also, in the step of forming the groove, the groove is preferably formed so as to penetrate through the first conductor layer, the substrate, and the second conductor layer. In the step of forming the wiring by filling the groove with the conductor, an electrode is connected to the first conductor layer and the second conductor layer, and the groove is preferably filled with the conductor by an electroplating process.

By using this method, a wiring can be readily formed.

Further, according to the present invention, a first resist film is preferably bonded to the surface of the first conductor layer of the board, and a second resist film is preferably bonded to the surface of the second conductor layer. The groove is preferably formed so as to penetrate through the first resist film and the second resist film. The step of forming the wiring by filling the groove with the conductor preferably includes: covering the surface of the conductor on the side of the first resist film and the surface of the conductor on the side of the second resist film with a third resist film, after filling the groove with the conductor; leaving the region of the first resist film adjacent to the groove in the direction perpendicular to the extending direction of the groove when seen from the board surface side, and leaving the region of the first resist film for forming another wiring different from the wiring, and selectively removing the other regions of the first resist film; leaving the region of the second resist film adjacent to the groove in the direction perpendicular to the extending direction of the groove when seen from the board surface side, and leaving the region of the second resist film for forming yet another wiring different from the wiring, and selectively removing the other regions of the second resist film; and forming the wiring, another wiring formed by the first conductor layer, and yet another wiring formed by the second conductor layer by selectively removing the region of the first conductor layer not covered with the first resist film and the region of the second conductor layer not covered with the second resist film.

According to this invention, the first resist film is provided on the surface of the first conductor layer, and the second resist film is provided on the surface of the second conductor layer. Accordingly, when the conductor to fill the groove is formed, the plating can be prevented from precipitating on the surfaces of the first conductor layer and the second conductor layer.

In the step of forming the groove, the groove may be formed so as to penetrate through the first conductor layer and the substrate, but not to penetrate through the second conductor layer. In the step of forming the wiring by filling the groove with the conductor, an electrode may be connected to the second conductor layer, and the groove may be filled with the conductor by an electroplating process.

Further, a first resist film may be bonded to the surface of the first conductor layer of the board, and a second resist film may be bonded to the surface of the second conductor layer. The groove may be formed so as to penetrate through the first resist film, the first conductor layer, and the substrate. The step of forming the wiring by filling the groove with the conductor may include: covering the surface of the conductor on the side of the first resist film with a third resist film, after filling the groove with the conductor; leaving the region of the first resist film adjacent to the groove in the direction perpendicular to the extending direction of the groove when seen from the board surface side, and leaving the region of the first resist film for forming another wiring different from the wiring, and selectively removing the other regions of the first resist film; leaving the region of the second resist film adjacent to the groove in the direction perpendicular to the extending direction of the groove when seen from the board surface side, and leaving the region of the second resist film for forming yet another wiring different from the wiring, and selectively removing the other regions of the second resist film; and forming the wiring, another wiring formed by the first conductor layer, and yet another wiring formed by the second conductor layer by selectively removing a region of the first conductor layer not covered with the first resist film and the region of the second conductor layer not covered with the second resist film.

In this case, the groove is formed so as not to penetrate through the second conductor layer. Accordingly, metal precipitation on the surface of the second conductor layer on the opposite side from the substrate can be certainly prevented.

As described above, the present invention provides a printed wiring board that restrains increases in its size and has highly durable wirings, and also provides a method for manufacturing the printed wiring board.

### BRIEF DESCRIPTION OF THE DRAWINGS

The above and other objects, advantages and features of the present invention will be more apparent from the following description of certain preferred embodiments taken in conjunction with the accompanying drawings.

FIG. 1 is a perspective view of a printed wiring board according to an embodiment of the present invention.

FIG. 2 is a cross-sectional view showing a procedure for manufacturing the printed wiring board.

FIG. 3 is a cross-sectional view showing a procedure for manufacturing the printed wiring board.

FIG. 4 is a cross-sectional view showing a procedure for manufacturing the printed wiring board.

FIG. 5 is a cross-sectional view showing a procedure for manufacturing the printed wiring board.

FIG. 6 is a cross-sectional view showing a procedure for manufacturing a printed wiring board according to a modification of the present invention.

FIG. 7 is a cross-sectional view showing a procedure for manufacturing a printed wiring board.

### BEST MODE FOR CARRYING OUT THE INVENTION

The following is a description of an embodiment of the present invention.

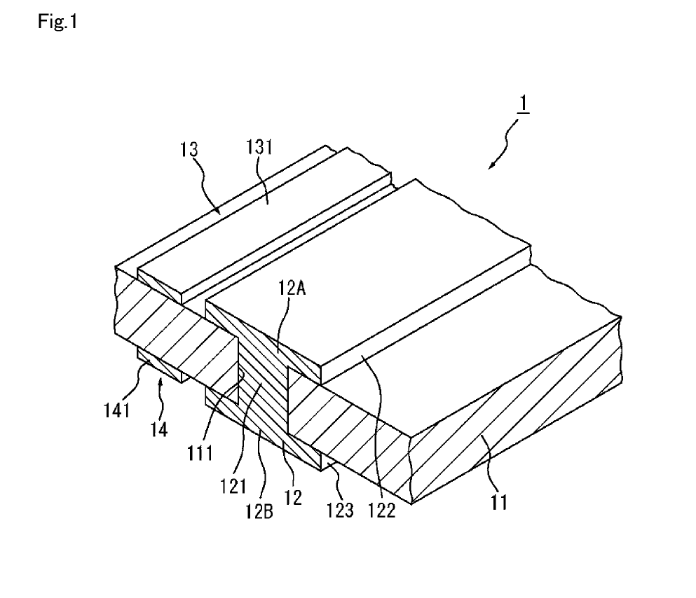

In FIG. 1, a printed wiring board 1 of this embodiment includes a substrate 11. A groove 111 that extends in a direction perpendicular to the thickness direction of the substrate 11 is formed in the substrate 11, and a wiring 12 is provided to fill the groove 111.

Next, the printed wiring board 1 of this embodiment is described in detail.

The printed wiring board 1 is a rigid wiring board in this embodiment.

The printed wiring board 1 is a double-sided circuit board that includes a pair of circuit layers 13 and 14 as well as the above mentioned substrate 11 and wiring 12. Alternatively, the printed wiring board 1 may be a single-sided circuit board having only one circuit layer formed thereon.

The substrate 11 is formed by stacking insulating resin layers such as resin layers containing glass cloth (glass fabrics). The substrate 11 may be a buildup layer that has a conductor circuit layer between the resin layers forming the substrate 11, and has vias formed in the resin layers.

The groove 111 is formed in the substrate 11. This groove 111 is formed across more than one insulating layer of the substrate 11. In this embodiment, the groove 111 penetrates through the upper and lower faces of the substrate 11, and extends in the direction perpendicular to the thickness direction of the substrate 11. In other words, the groove 111 extends along the board surface of the printed wiring board 1. The groove 111 is formed to have a slit-like shape.

This groove 111 is filled with the wiring 12.

The wiring 12 is made of copper, for example. The wiring 12 has a pair of end portions 12A and 12B protruding from the groove 111 in the wiring thickness direction, and the end portions 12A and 12B spread along the faces of the substrate 11 in a flange-like manner.

More specifically, the wiring 12 includes a wiring main body 121 filling the groove 111, and flange portions 122 and 123.

The wiring main body 121 fills the groove 111, and has a rectangular cross-section perpendicular to the board surface and the extending direction of the wiring 12. The wiring main body 121 is interposed between the pair of flange portions 122 and 123 spreading along the faces of the substrate 11.

The flange portions 122 and 123 extend together with the wiring main body 121 in the extending direction of the wiring main body 121. The flange portions 122 and 123 spread from the wiring main body 121 in a direction perpendicular to the extending direction of the wiring main body 121, when seen from the board surface side. The flange portions 122 and 123 are designed to spread toward both sides of the wiring main body 121, when seen from the board surface side. In other words, the wiring 12 has an I-like cross-sectional shape.

The thickness of each of the flange portions 122 and 123 is much smaller than the depth of the groove 111.

The wiring 12 having such a shape is used as a power wire.

The circuit layer 13 is formed by a wiring 131 formed on one of the faces (the upper face) of the substrate 11. The circuit layer 14 is formed by a wiring 141 formed on the other one of the faces (the lower face) of the substrate 11.

The wirings 131 and 141 are formed along the faces of the substrate 11, and are not buried in the substrate 11. The wirings 131 and 141 forming the circuit layers 13 and 14 are signal lines.

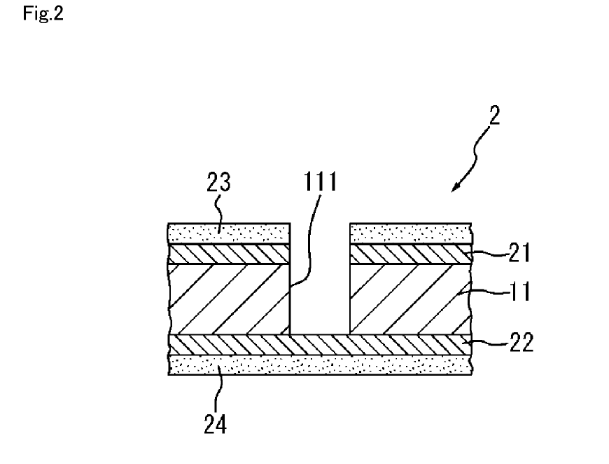

Referring now to FIGS. 2 through 4, a method for manufacturing the above printed wiring board 1 is described.

First, as shown in FIG. 2, a board 2 having a pair of conductor layers (a first conductor layer 21 and a second conductor layer 22) formed on the upper and lower faces of the substrate 11 is prepared. This board 2 includes a first resist film 23 to cover the first conductor layer 21, and a second resist film 24 to cover the second conductor layer 22.

Here, the first conductor layer 21 and the second conductor layer 22 are made of a metal such as copper.

The groove 111 is then formed in the substrate 11. The groove 111 is formed by emitting a laser beam from the side of the first resist film 23. The groove 111 penetrates through the first resist film 23, the first conductor layer 21, and the substrate 11, so that the second conductor layer 22 is exposed through the bottom portion.

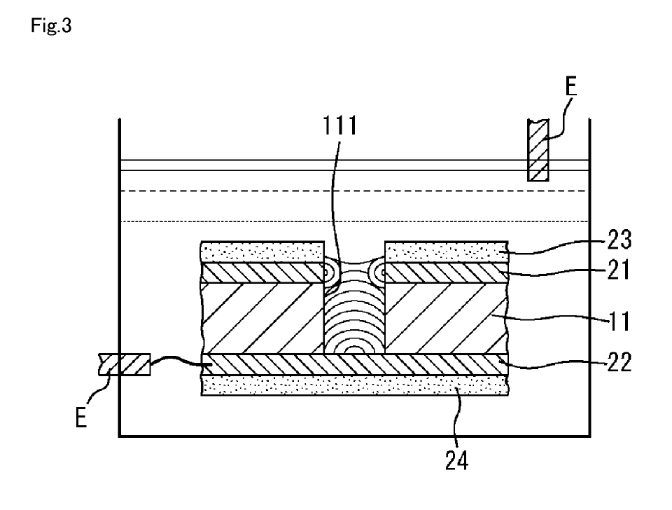

After that, electroplating is performed on the inside of the groove 111 of the board 2, as shown in FIG. 3. FIG. 3 schematically shows the situation where the electroplating is performed. Here, an electrode E is connected to the second conductor layer 22, to perform the electroplating.

Through this electroplating, the metal such as copper precipitates to fill the groove 111, and forms the wiring main body 121. As the groove 111 is filled in this manner, metal precipitation on the surface (the opposite face from the substrate 11) of the second conductor layer 22 can be certainly prevented. Accordingly, etching on the second conductor layer 22 becomes easier.

Where the second conductor layer 22 is to be exposed through the bottom portion of the groove 111, the width of the groove 111 (the length of the groove 111 in a direction perpendicular to the extending direction) is preferably about 50 μm, for example, in view of the precipitation properties of the electroplating.

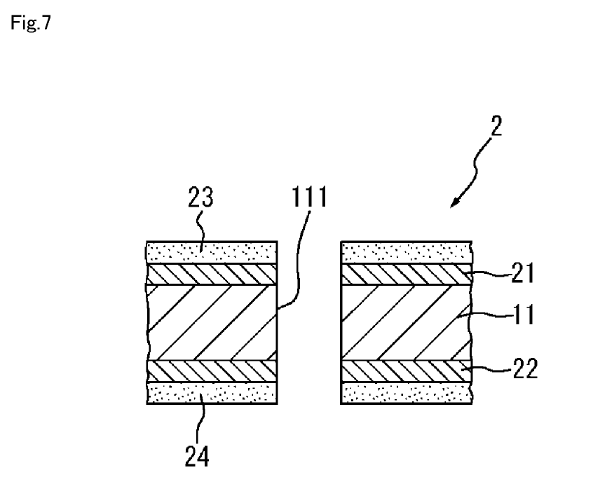

Alternatively, the groove 111 may penetrate the first resist film 23, the first conductor layer 21, the substrate 11, the second conductor layer 22, and the second resist film 24, as shown in FIG. 7.

In that case, an electrode is connected to the first conductor layer 21 and the second conductor layer 22, and the electroplating is then performed. With this arrangement, the groove 111 can be filled more certainly.

Here, the “electroplating thickness×2” is made equal to or greater than the groove width of the groove 111 so that the groove 111 can be more easily filled with the electroplating.

In a case where the groove 111 penetrates through the first conductor layer 21, the substrate 11, and the second conductor layer 22, as shown in FIG. 7, the first resist film 23 and the second resist film 24 may not be provided. In this case, plating can be performed on the surfaces of the first conductor layer 21 and the second conductor layer 22, and the allowable current for the wiring 12 can be increased. However, in view of the etching to be performed on the first conductor layer 21 and the second conductor layer 22, it is preferable to provide the first resist film 23 and the second resist film 24.

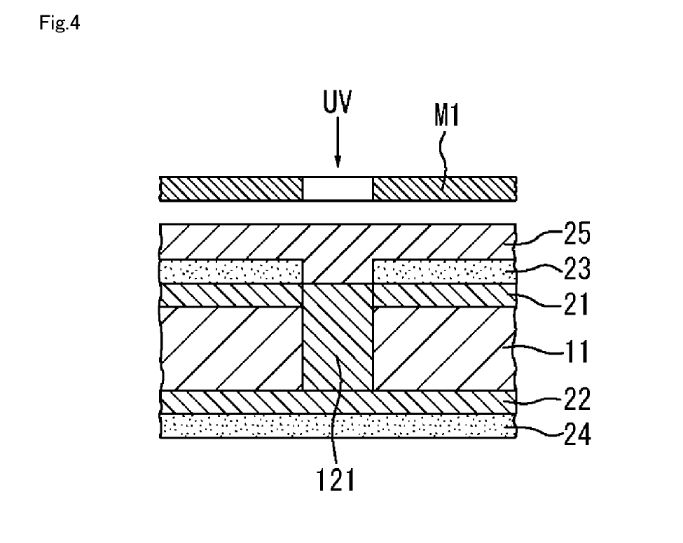

A resist 25 is then applied so as to cover the first resist film 23 and the wiring main body 121, as shown in FIG. 4.

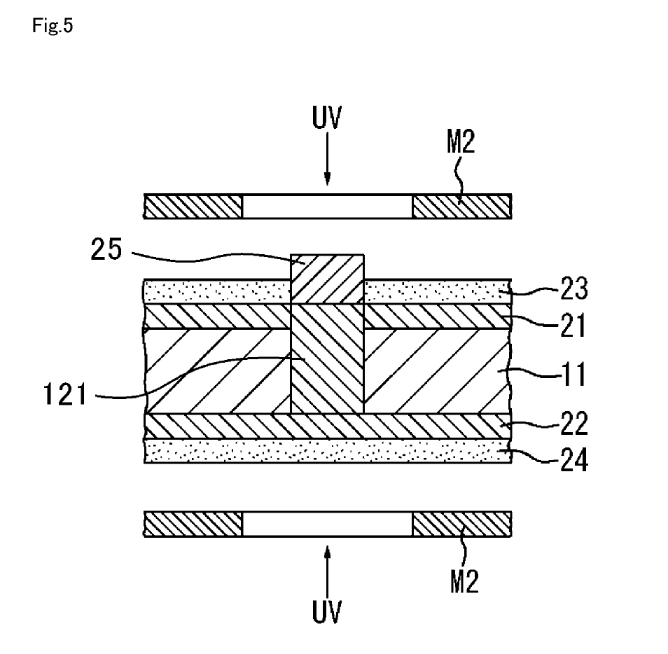

The board 2 is illuminated with light (an ultraviolet ray, for example) via a mask M1 having a predetermined opening formed therein. By doing so, the resist 25 (the third resist film) 25 on the wiring main body 121 is hardened. After that, the non-illuminated portion of the resist 25 is removed. In this manner, the upper portion of the wiring main body 121 (the face on the side of the first resist film 23) is covered with the resist 25, and is thus protected (see FIG. 5).

In the case where the groove 111 penetrates through the first resist film 23, the first conductor layer 21, the substrate 11, the second conductor layer 22, and the second resist film 24, as shown in FIG. 7, the resist 25 is applied so as to cover the second resist film 24 and the wiring main body 121, and the resist 25 on the wiring main body 121 is hardened. By doing so, the upper portion of the wiring main body 121 (the face on the side of the first resist film 23) and the lower portion of the wiring main body 121 (the face of the side of the second resist film 24) are covered with the resist 25, and are thus protected.

The board 2 is then illuminated with light (an ultraviolet ray, for example) via a mask M2 having a predetermined opening formed therein, as shown in FIG. 5.

Here, on the resist 25 on the wiring main body 121 and the first resist film 23, light is emitted on the regions located on both sides of the groove 111 when seen from the board surface side (or a pair of regions adjacent to the groove 111 in the direction perpendicular to the extending direction of the groove 111 when seen from the board surface side) and the region forming another wiring 131 different from the wiring 12. In FIG. 5, the opening of the mask M2 for illuminating the region forming another wiring 131 with light is not shown. Also, in the case where the groove 111 penetrates through the first resist film 23, the first conductor layer 21, the substrate 11, the second conductor layer 22, and the second resist film 24, as shown in FIG. 7, light is also emitted onto the resist film 25 and the first resist film 23.

On the second resist film 24, light is emitted onto the region overlapping with the groove 111 when seen from the board surface side, the regions located on both sides of the groove 111 (the pair of regions adjacent to the groove 111 in the direction perpendicular to the extending direction of the groove 111 when seen from the board surface side), and the region forming yet another wiring 141 different from the wiring 12. In FIG. 5, the opening of the mask M2 for illuminating the region forming yet another wiring 141 with light is not shown.

In the case where the groove 111 penetrates through the first resist film 23, the first conductor layer 21, the substrate 11, the second conductor layer 22, and the second resist film 24, as shown in FIG. 7, light may be emitted onto the regions of the second resist film 24 located on both sides of the groove 111 (the pair of regions adjacent to the groove 111 in the direction perpendicular to the extending direction of the groove 111 when seen from the board surface side) and the region forming yet another wiring 141 different from the wiring 12.

After that, the non-illuminated portions of the first resist film 23 and the second resist film 24 are selectively removed. Specifically, the non-illuminated portions are removed by immersing the board 2 in an alkaline solution or the like.

Of the first conductor layer 21, the region not covered with the first resist film 23 is then selectively removed, and the flange portion 122 of the wiring 12 and the wiring 131 are formed. For example, of the first conductor layer 21, the region not covered with the first resist film 23 is selectively removed by wet etching. Since being covered with the resist 25, the wiring main body 121 can be prevented from being etched.

Of the second conductor layer 22, the region not covered with the second resist film 24 is selectively removed, and the flange portion 123 of the wiring 12 and the wiring 141 are formed. For example, of the second conductor layer 22, the region not covered with the second resist film 24 is selectively removed.

After that, the first resist film 23, the second resist film 24, and the resist 25 are removed.

Through the above-described procedures, the printed wiring board 1 shown in FIG. 1 is manufactured.

Next, the effects of this embodiment are described.

In this embodiment, the wiring 12 is buried in the groove 111 formed in the substrate 11.

Accordingly, even if the width of the wiring is the same as that of a conventional wiring, a large cross-sectional area of the wiring can be secured by adjusting the depth of the groove 111. With this structure, the durability of the wiring 12 can be made higher, and an increase in size of the printed wiring board 1 can be prevented.

Particularly, in this embodiment, the wiring 12 includes the wiring main body 121 to fill the groove 111, and the flange portions 122 and 123. With this structure, the cross-sectional area of the wiring 12 can be large, and the durability of the wiring 12 can be made higher.

In addition to that, the wiring 12 is a power wire in this embodiment. To supply power to the electronic components mounted on the printed wiring board 1, a high current flows through the power wire. Therefore, a large cross-sectional area of the power wire needs to be secured by increasing the wiring width and thickness. As the wiring 12 of this embodiment is a power wire, an increase in size of the printed circuit board 1 can be certainly prevented, and the durability of the power wire can be made higher.

The wiring 12 also has the flange portions 122 and 123 extending along the surface of the substrate 11. Spreading along the surface of the substrate 11 from the wiring main body 121, the flange portions 122 and 123 can prevent the wiring main body 121 from slipping out of the groove 111.

Further, during the manufacture of the printed wiring board 1 in this embodiment, the first resist film 23 is provided on the surface of the first conductor layer 21, and the second resist film 24 is provided on the surface of the second conductor layer 22. With this arrangement, precipitation of the plating on the surfaces of the conductor layers 21 and 22 can be prevented when the conductor to fill the groove 111 is formed.

Also, since the first resist film 23 is provided on the surface of the first conductor layer 21 while the second resist film 24 is provided on the surface of the second conductor layer 22, contamination of the surface of each of the conductor layers 21 and 22 can be prevented at the time of laser illumination to form the groove 111.

The present invention is not limited to the above-described embodiment, but changes and modifications within the scope of the invention are included in the present invention.

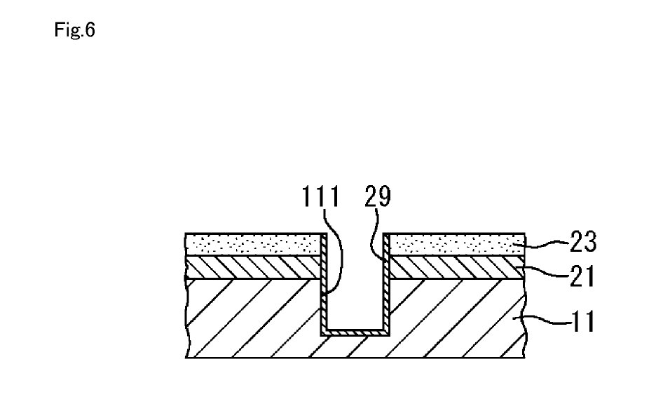

For example, the groove 111 is a through groove that penetrates through the substrate 11. However, the groove 111 is not limited to that, and may not penetrate through the substrate 11. For example, in a case where a board having the conductor layer 21 is bonded only to one side thereof is used as the board 2, as shown in FIG. 6, a groove 111 that does not penetrate through the substrate 11 may be formed. In this case, a metal thin film 29 to be a base is provided on the bottom portion and sidewalls of the groove 111. After that, electroless plating process is performed to provide the wiring main body 121. The metal thin film 29 to be the base can be formed by a electroless plating process or a sputtering technique.

Further, in the above-described embodiment, the wiring 12 has the pair of flange portions 122 and 123. However, the wiring 12 is not limited to that, and may have only one of the flange portions and may have a T-like cross-section. With such a structure, a large cross-sectional area can also be secured for the wiring, and the durability of the wiring can be made higher accordingly.

Also, the flange portion 122 spreads along both regions adjacent to the groove 111 in the direction perpendicular to the extending direction of the groove 111 when seen from the board surface side. However, the flange portion 122 may spread only along one of the regions adjacent to the groove 111. The flange portion 123 may also spread only along one of the regions adjacent to the groove 111. For example, a wiring that has a U-like shape in cross-section in the direction perpendicular to the extending direction may be formed.

The flange portions 122 and 123 may not even be provided.

Further, in the above-described embodiment, the printed circuit board is a rigid wiring board. However, the printed wiring board is not limited to that, and may be a rigid flexible wiring board that has the groove 111 and the wiring 12 provided in the rigid portion.

In this embodiment, the wiring 12 is formed by electroplating, and therefore, the wiring 12 is relatively hard. If the wiring 12 is provided in the rigid portion, the flexibility of the wiring board at the flexible portion is not lost.

Further, the printed wiring board may be a flexible wiring board. Alternatively, the groove 111 and the wiring 12 may be provided in the flexible portion of a rigid flexible wiring board.

Also, in this embodiment, the wiring 12 is a power wire. However, the wiring 12 is not limited to that, and may be used as a wire that is not a power wire and requires high heat radiation properties. For example, the wiring 12 may be used as a wire that is pulled out from a component mounting terminal with a large amount of heat generation, or as a wire provided near such a component mounting terminal.

1. A printed wiring board comprising
a substrate,
a groove that extends in a direction perpendicular to a thickness direction of said substrate being formed in said substrate,
a wiring being provided to fill said groove.

2. The printed wiring board according to claim 1, wherein
said wiring fills said groove and has an end portion protruding from said groove in a wiring thickness direction, said end portion spreading along said substrate in a flange-like shape.

3. The printed wiring board according to claim 1, wherein
said groove is a through groove that penetrates through said substrate, and
said wiring has a pair of end portions each protruding from an opening of said groove in a wiring thickness direction, said end portions spreading along said substrate in a flange-like shape.

4. The printed wiring board according to claim 1, wherein
said wiring is a power wire, and
a signal line formed by another wiring different from said wiring is formed on said substrate.

5. The printed wiring board according to claim 1, which printed wiring board is a rigid wiring board or a rigid flexible wiring board, wherein
said groove and said wiring are provided in a rigid region.

6. A method for manufacturing a printed wiring board, comprising:
forming a groove in a board having a substrate, said groove extending in a direction perpendicular to a thickness direction of said substrate; and
forming a wiring by filling said groove with a conductor.

7. The method according to claim 6, wherein
said board includes said substrate and a first conductor layer provided on said substrate,
said forming said groove includes forming said groove to penetrate through said first conductor layer and reach an inside of said substrate, and
said forming said wiring includes forming said wiring that fills said groove and has an end portion protruding from said groove in an wiring thickness direction and spreading along said substrate in a flange-like shape, by filling said groove with said conductor and selectively removing said first conductor layer.

8. The method according to claim 7, wherein
said board includes a second conductor layer that is provided on the opposite side of said substrate from said first conductor layer,
said forming said groove includes forming said groove to penetrate through said first conductor layer and said substrate, and
said forming said wiring includes forming said wiring that fills said groove and has a pair of end portions each protruding from an opening of said groove in an wiring thickness direction and spreading along said substrate in a flange-like shape, by filling said groove with said conductor and selectively removing said first conductor layer and said second conductor layer.

9. The method according to claim 8, wherein
said forming said groove includes forming said groove to penetrate through said first conductor layer, said substrate, and said second conductor layer, and
said forming said wiring by filling said groove with said conductor includes connecting an electrode to said first conductor layer and said second conductor layer, and filling said groove with said conductor by an electroplating process.

10. The method according to claim 9, wherein
a first resist film is bonded to a surface of said first conductor layer of said board, and a second resist film is bonded to a surface of said second conductor layer,
said groove is formed to penetrate through said first resist film and said second resist film,
said forming said wiring by filling said groove with said conductor includes:
covering a surface of said conductor on a side of said first resist film and a surface of said conductor on a side of said second resist film with a third resist film, after filling said groove with said conductor;
leaving a region of said first resist film adjacent to said groove in the direction perpendicular to the extending direction of said groove when seen from a board surface side, and leaving a region of said first resist film for forming another wiring different from said wiring, and selectively removing the other regions of said first resist film;
leaving a region of said second resist film adjacent to said groove in the direction perpendicular to the extending direction of said groove when seen from said board surface side, and leaving a region of said second resist film for forming yet another wiring different from said wiring, and selectively removing the other regions of said second resist film; and
forming said wiring, said another wiring formed by said first conductor layer, and said yet another wiring formed by said second conductor layer by selectively removing a region of said first conductor layer not covered with said first resist film and a region of said second conductor layer not covered with said second resist film.

11. The method according to claim 8, wherein
said forming the groove includes forming said groove to penetrate through said first conductor layer and said substrate, but not to penetrate through said second conductor layer, and
said forming the wiring by filling said groove with said conductor includes connecting an electrode to said second conductor layer and filling said groove with said conductor by an electroplating process.

12. The method according to claim 11, wherein
a first resist film is bonded to a surface of said first conductor layer of said board, and a second resist film is bonded to a surface of said second conductor layer,
said groove is formed to penetrate through said first resist film, said first conductor layer, and said substrate,
said forming the wiring by filling said groove with said conductor includes:
covering a surface of said conductor on a side of said first resist film with a third resist film, after filling said groove with said conductor;
leaving a region of said first resist film adjacent to said groove in the direction perpendicular to the extending direction of said groove when seen from a board surface side, and leaving a region of said first resist film for forming another wiring different from said wiring, and selectively removing the other regions of said first resist film;
leaving a region of said second resist film adjacent to said groove in the direction perpendicular to the extending direction of said groove when seen from said board surface side, and leaving a region of said second resist film for forming yet another wiring different from said wiring, and selectively removing the other regions of said second resist film; and
forming said wiring, said another wiring formed by said first conductor layer, and said yet another wiring formed by said second conductor layer by selectively removing a region of said first conductor layer not covered with said first resist film and a region of said second conductor layer not covered with said second resist film.

13. The printed wiring board according to claim 1, wherein
said groove is formed across a plurality of insulating layers forming said substrate.
